(19) United States
(12) Patent Application Publication
(10) Pub. No.: US 2008/0309349 A1
(43) Pub. Date: Dec. 18, 2008

(54) Flexible interposer system

(75) Inventor: Albert Sutono, San Jose, CA (US)

Correspondence Address: LECROY CORPORATION, 700 CHESTNUT RIDGE ROAD, CHESTNUT RIDGE, NY, 10977, US

(73) Assignee: Computer Access Technology Corporation, Chestnut Ridge, NY (US)

(21) Appl. No.: 11/818,583

(22) Filed: Jun. 15, 2007

(51) Int. Cl. G01R 31/28

(52) U.S. Cl. 324/537

(57) ABSTRACT

A system for detecting communication signals between two processing devices may include an interposer unit that comprises an active signal conditioning module to condition and convey portions of signals (e.g., 5 GHz or above) to a receiver, such as a measurement instrument. In an illustrative example, the interposer unit may convey high speed signals between a device under test (DUT) and a motherboard designed to operate with the DUT. A measurement instrument, such as a protocol analyzer, for example, may monitor signals on the interposer unit through a flexible transmission line (e.g., flex circuit) extending between the measurement instrument and the interposer unit. In various embodiments, active signal conditioning on the flexible transmission line may substantially mitigate degradation of the portion of the signals conveyed from the interposer unit to the instrument.

### BACKGROUND

Data rates continue to increase in digital systems, communication systems, computer systems, and in other applications. In such applications, various devices communicate data using signals that may be encoded with information in the form of signal levels (e.g., amplitude) in certain intervals of time. Proper decoding of signals, for example, may involve measuring small signal levels in the correct time intervals. As data rates increase, margins of error for the signal level timing tend to decrease.

Likewise, operating frequencies for some analog signal processing systems continue to increase along with advances in telecommunication technologies, for example.

Various test and measurement equipment may be used to verify signal integrity in analog and digital systems. For example, oscilloscopes may be used to measure analog waveforms, and protocol analyzers may be used to monitor data in digitally formatted signals.

In a typical measurement set-up example, a measurement cable assembly may connect a protocol analyzer to one or more digital data lines on a device under test (DUT). The cable assembly may have multiple parallel conductive paths that serve as transmission lines for the signals to be monitored. In some cases, each conductive path may include a combination of different transmission line sections, which may include any or all of, for example, an interface to the DUT, traces on a printed circuit board (PCB), and a flexible cable.

### SUMMARY

A system for detecting communication signals between two processing devices may include an interposer unit that comprises an active signal conditioning module to condition and convey portions of signals (e.g., 5 GHz or above) to a receiver, such as a measurement instrument. In an illustrative example, the interposer unit may convey high speed signals between a device under test (DUT) and a motherboard designed to operate with the DUT. A measurement instrument, such as a protocol analyzer, for example, may monitor signals on the interposer unit through a flexible transmission line (e.g., flex circuit) extending between the measurement instrument and the interposer unit. In various embodiments, active signal conditioning on the flexible transmission line may substantially mitigate degradation of the portion of the signals conveyed from the interposer unit to the instrument.

Various embodiments may provide one or more advantages. For example, an interposer unit of substantially reduced size and form factor may substantially maintain signal integrity over a wide bandwidth for signals that are conveyed between the DUT and the motherboard, for example. Some embodiments may include an interposer unit substantially reduced in size, wherein the substantially the only components provided include a printed circuit substrate, a tap resistor (e.g., surface mount, integrated, or the like) for each signal to be tapped, and (optionally) connectors to interface to the DUT, motherboard, and flexible wiring assembly. As such, some embodiments of the interposer unit may be reduced to a small form factor of approximately the width of the host/DUT interface. A flexible wiring assembly with active signal conditioning (e.g., amplification) may facilitate connection between an interposer unit and a measurement instrument, and may also extend the achievable cable length that may be used to measure high speed signals being conveyed across an interposer unit, for example.

The details of one or more embodiments are set forth in the accompanying drawings and the description below. Other features, objects, and advantages will be apparent from the description and drawings, and from the claims.

### DESCRIPTION OF DRAWINGS

FIG. 1 shows an exemplary measurement system to measure high speed signals.

FIG. 2 shows a view of an exemplary interposer unit and connector assembly structure for tapping high speed signals.

FIG. 3 shows an exemplary electrical circuit layout for tapping and routing transmission lines through an interposer unit.

FIG. 4 shows an exemplary electrical circuit representation of a signal path for high speed signal amplification.

FIG. 5 shows an exemplary method of attaching flex circuitry to a cable within a connector assembly.

FIG. 6 shows an exemplary multilayer circuit board layout for dampening resonance at a via.

FIG. 7 shows an exemplary graph of the effect a dampening resistor may have on frequency response at a via using the circuit layout in FIG. 6.

FIG. 8 shows an exemplary circuit schematic for dampening resonance at a via using a stub in serial connection with a damping resistor.

### DETAILED DESCRIPTION OF ILLUSTRATIVE EXAMPLES

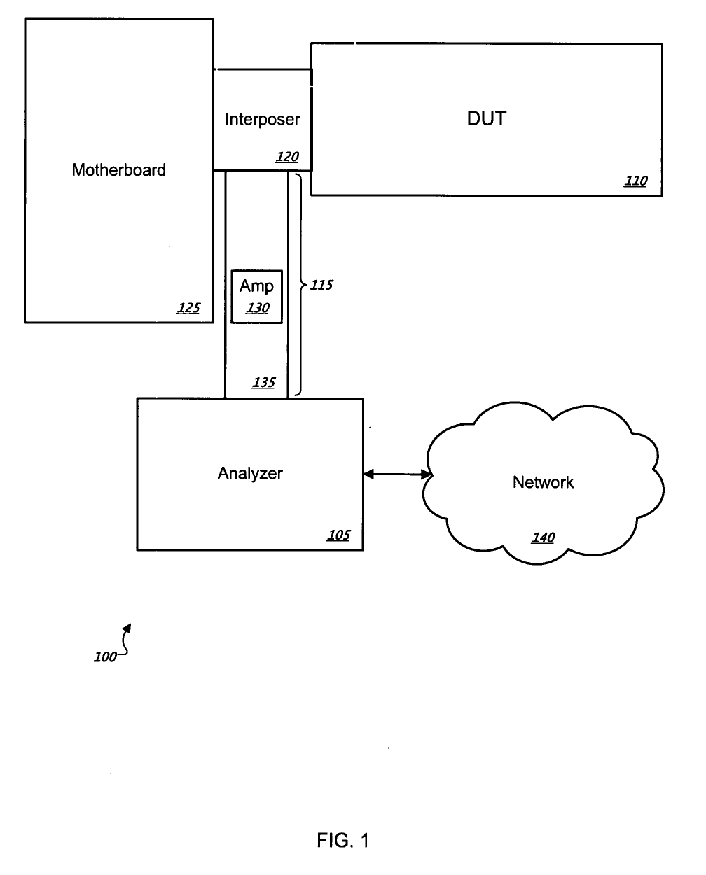

FIG. 1 shows an exemplary measurement system 100 for measuring one or more high speed signals. In some examples, the system 100 may include a waveform processing system and/or involve measuring high frequency (e.g., above about 5 GHz) analog signals and/or high data rate (e.g., above about 5 Gbits/second) digital signals. The system 100 of this example includes an analyzer 105 (e.g., protocol analyzer, oscilloscope) to make measurements of high speed signals being communicated between a device under test (DUT) 110 and a motherboard 125, decode and display the information. The system 100 includes an interposer unit 120 that is installed between the DUT 110 and the motherboard 125. To measure signals communicated between the DUT 110 and the motherboard 125, the interposer unit 120 taps into one or more selected signals. The tapped signals are conveyed from the interposer unit 120 to the analyzer 105 via a connector assembly 115. The connector assembly 115 includes amplifier circuitry 130 to condition (e.g., filter, equalize and/or amplify) the high speed signals for transmission to and/or from the analyzer 105, and a cable assembly 135. In an illustrative example, the interposer unit 120, once installed between the motherboard 125 and the DUT 110, taps a fraction of one or more DUT signals being communicated between the DUT 110 and motherboard 125, and directs the tapped portion of the signals over the connector assembly 115. Within the connector assembly 115, the tapped signals are conditioned by the amplifier circuitry 130 as they are conveyed to the analyzer 105. The amplifier circuitry 130 conditions (e.g., amplifies, buffers, delays, filters, impedance matches) the signals for transmission through the cable 135 to the analyzer 105. A user may access the analyzer 105 through a network 140.

The interposer unit 120 may be implemented, for example, on a single-sided or a multi-layer printed circuit board (PCB) (e.g., 1-30 layers PCB) by forming conductive traces (e.g., by etching copper or copper alloys, conductive inks, or the like) onto one or more layers of a dielectric substrate. In some embodiments, the interposer unit 120 may be implemented using any suitable standard and/or non-standard materials for constructing a substrate, which may include, but are not limited to, a PCB, flexible circuitry, or ceramic substrate, for example. By way, of example and not limitation, embodiments may be fabricated using materials that include FR-2, FR-4, Rogers 3000, Rogers 3200, Rogers 4000, Rogers Duroid, thermoplastic chloro-fluorocopolymer, thermoset ceramic loaded plastic, Teflon type GT or GX, polyimide, polystyrene and cross-linked polystyrene, ceramic materials and/or a combination of these or other suitable materials.

In some other embodiments, the interposer unit 120 may comprise a flex circuit constructed using materials and techniques similar to those that may be used as a flexible substrate for the amplifier circuitry 130. Examples of flexible substrates for circuits are described with reference, for example, to FIG. 1.

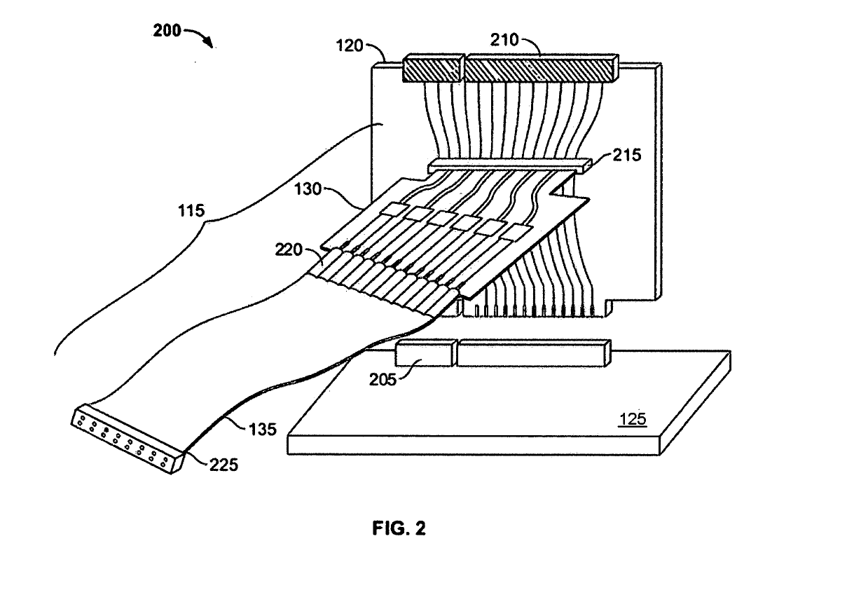

In some embodiments, the interposer unit 120 and/or the connector assembly 115 may incorporate one or more structures to improve the integrity of signals that propagate from the DUT 110 to the analyzer 105, thus improving high speed signal measurements. Combinations of such features may, for example, increase the effective measurement bandwidth of waveform processing systems, such as protocol analyzers, multimeters, logic analyzers, logic probes, digital oscilloscopes, and other varieties of electronic and/or automatic test equipment. In some examples, the interposer unit 120 and the connector assembly 115 may conduct any number, for example, up to at least 16, 32, or more channels of high speed (e.g., 5 Gbits/second or above digital, 5 GHz or above analog) single-ended and/or differential signals from the DUT 110 to the analyzer 105. Exemplary embodiments of the interposer unit 120 and connector assembly 115 are described in further detail with reference, for example, to FIG. 2.

The DUT 110 may be any unit (e.g., printed circuit card, flexible assembly, hybrid module, or a combination of such elements) communicating with the motherboard 125, including but not limited to a graphics card, sound card, multimedia card, memory board, or device controller. In some examples, the DUT 110 may be a telecommunication device or a computer network device that uses high speed signals to transmit digital data with data rates greater than 1 Gbit/second or analog signals with frequency content up to at least 1 GHz (e.g., 40 GHz, 40 Gbps). For example, the DUT 110 may use communication networks that implement standard protocols, such as a Synchronous Optical Networking (SONET) OC-768 specification, a Generation 2 Peripheral Component Interconnect (PCI) Express protocol, FireWire 400, Universal Serial Bus (USB) 2.0, Serial ATA (SATA) 6.0, HyperTransport bus, or other communication protocols. The common connection between the DUT 110 and the motherboard 125 can be through, for example, a PCI Express (PCIe) bus slot, PCI slot, or PCI-X slot bus technology.

Interfacing between the DUT 110 and the motherboard 125, the interposer unit 120 may provide, in some embodiments, a pass through to substantially convey signals between the DUT 110 and the motherboard 125. These signals may be single-ended and/or differential, and they may include power, and/or reference voltage and/or current signals. In some embodiments, the interposer unit 120 may include additional circuitry, such as damping resistors, for example. Such embodiments may advantageously optimize signal integrity and/or reduce resonances, for example, which may be related to parasitic effects, impedance discontinuities, electromagnetic interference, or the like. Exemplary implementations using damping resistors are described in further detail with reference, for example, to FIGS. 6-8.

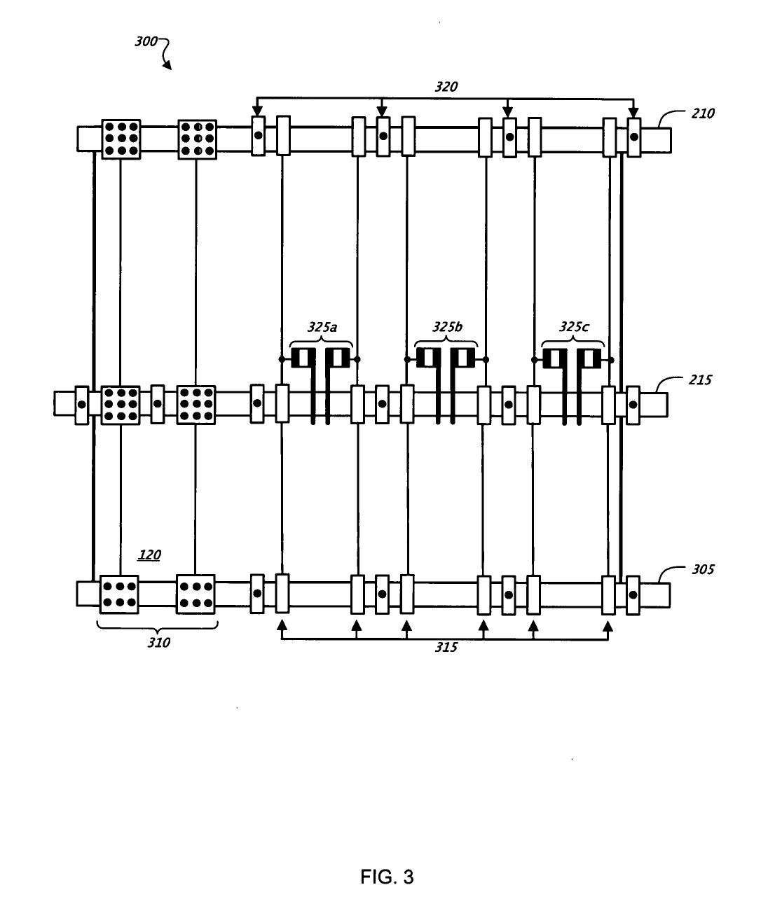

Using the interposer unit 120, the system 100 may tap into one or more signals (e.g., high frequency analog and/or high data rate digital signals) being communicated between the DUT 110 and the motherboard 125. In some embodiments, the signals may be tapped using tapping resistors. Exemplary embodiments of tapping resistors are described in further detail with reference, for example, to FIG. 3. In turn, the interposer unit 120 directs the tapped signals to the analyzer 105 via the connector assembly 115.

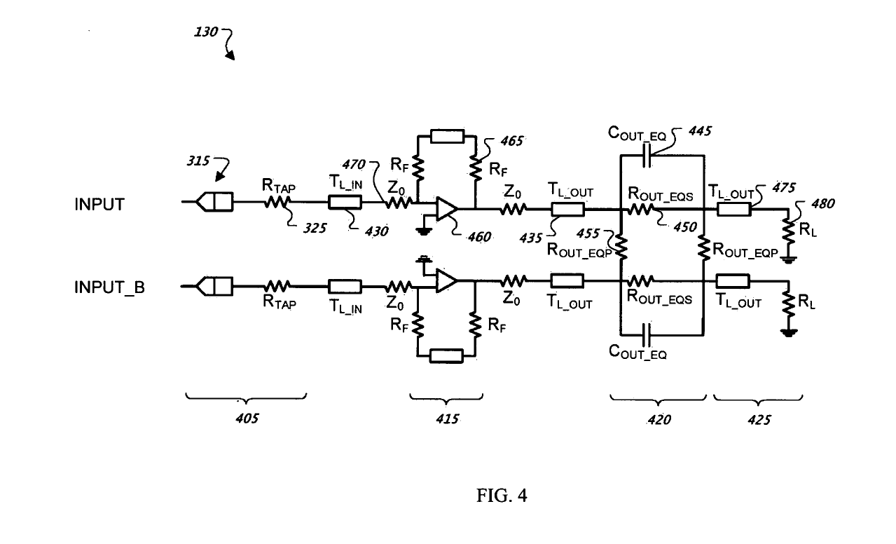

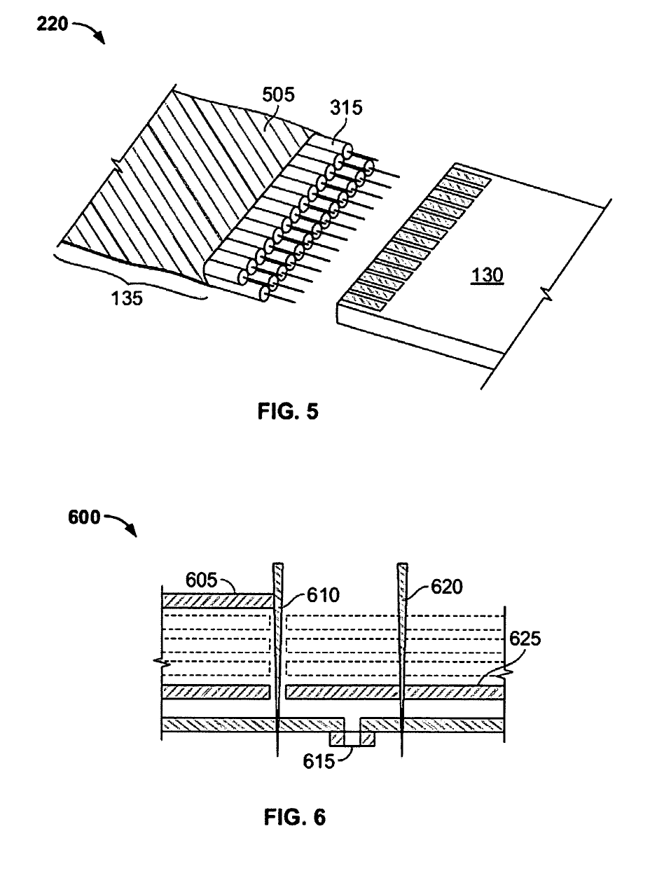

The connector assembly 115 includes the cable 135 and at least one amplification stage that includes the amplifier circuitry 130. In various examples, the amplifier circuitry 130 may be deployed on flexible substrate(s) for circuit components. For example, the interconnects on the flexible substrate may be etched in high elongation copper (ED), roll annealed copper (RA), printed in silver conductive ink, or created using metal foils such as Constantan, stainless steel, beryllium-copper or gold. A substrate for an embodiment of the amplifier circuitry 130 may, for example, be single-sided, double-sided, or may have multiple layers. The substrate material of the amplifier circuitry 130 may be created from, but is not limited to, any of the following materials: polyimide (PI), KAPTON™ or thin bendable semi rigid material (e.g., bendflex), Liquid Crystal Polymer (LCP), or flex-based materials from Taconic Corp., or any flexible materials suitable for printed circuit construction. For example, a flexible substrate for a circuit may be configured to provide features such as conductive traces, component pads, vias, one or more conductive layers, a minimum bend radius of approximately ten times the thickness of the substrate, rigidizers and/or stiffeners, or a combination of these or other features. In some embodiments, the amplifier circuitry 130 can have a protective flexible cover layer. Various active and/or passive electronic circuit components may be attached to the flexible substrate. Examples of the amplifier circuitry are further described with reference, for example, to FIGS. 4-5.

In some implementations, the amplifier circuitry 130 directly receives the tapped signals as they leave the interposer unit 120, with the cable 135 conveying the tapped signals the rest of the way between the DUT 110 and the analyzer 105 to form a high speed transmission signal testing system. An exemplary embodiment of a system for testing high speed signal transmissions is described in U.S. patent application Ser. No. 11/508,509 entitled “High Speed Signal Transmission” by Shaul et al., filed on Aug. 22, 2006. For purposes of an illustrative example, the disclosures of the detailed description portions and corresponding figures from U.S. patent application Ser. No. 11/508,509 are incorporated herein by reference. To the extent any particular features are described in the incorporated disclosures as important or necessary, it will be understood that such characterizations refer to that document and are not intended to apply to all embodiments disclosed herein.

In other implementations, the connector assembly 115 may include any series arrangement of the cable 135 and the amplifier circuitry 130. For example, the amplifier circuitry 130 may connect substantially directly to analyzer 105. In some embodiments, the amplifier circuitry 130 and the cable 135 may form a flexible wiring assembly. In some implementations, multiple stages of amplification may be used, for example, to realize extended lengths for the connector assembly or to provide independent stages of gain, each of which may include frequency response shaping filter elements (e.g., high pass, low pass, band boost, notch, or the like). Various embodiments may provide user-selectable tuning of gain and frequency response shaping characteristics. Some embodiments may optionally provide access to filtered and/or unfiltered outputs, or to intermediate signals taken from within a series of cascaded amplification stages, for example, at the interface to the analyzer 105.

In various embodiments, an amplifier module, such as the amplifier circuitry 130 mounted on a flex circuit, may be optionally arranged with one or more cables, such as the cable 135, to couple signals between the interposer unit 120 and a receiver, such as the analyzer 105. In one illustrative example, a cable may connect the interposer unit 120 to the amplifier module, and a second cable may connect the amplifier module to the receiver. In another illustrative example, the amplifier circuitry is implemented on a flex circuit capable of extending between and directly coupling the interposer cart 120 to the analyzer 105. In yet another illustrative example, the amplifier module may be configured to connect directly to the analyzer 105 and connect to the interposer cared 120 optionally through a cable similar to the cable 135.

In various implementations, the amplifier circuitry 130 may amplify the signals intercepted by the interposer unit 120. In some implementations, the amplifier circuitry 130 is powered by the power signal tapped from the motherboard 125 by the interposer unit 120, or by the analyzer 105 through the assembly 115. In some examples, transistor amplification may be used. The amplitude gain of the amplifier stage may be, for example, substantially greater than unity to compensate the attenuation −introduced by the tapping resistor on the interposer board 120. In various embodiments, the signal gain within a bandwidth of interest may be, for example, about 1, 2, 5, 10, 20, 40, 60, 75, 90 or 100, or in the range of about 10-500. In some other embodiments, the amplitude gain may be substantially unity, such as either −1 or 1. In some embodiments, the amplitude gain may be less than unity. In some implementations, the amplifier could operate in linear and limiting mode, for example, such that it generates substantially constant output amplitude over a range of input signal values. By way of example, and not limitation, the tapping may provide of about 17-20 dB signal attenuation so as to substantially avoid signal distortion on the channel under test.

In an example implementation, the amplifier circuitry 130 may amplify low voltage differential signals (LVDS) or CML (Current Mode Logic) or other standard or custom signaling protocols for transmission to the analyzer 105, which may be, for example, a protocol analyzer configured to measure and/or further process the signals. In some examples, the amplifier circuitry 130 may include multiple circuits to process the received signals. These additional circuits may include, for example, circuitry to attenuate, limit, terminate, condition, and/or improve the integrity of signals conveyed from the DUT 110 to the analyzer 105. In some embodiments, the amplifier circuitry 130 may provide conditioning such as filtering, delay (e.g., tapped delay lilies), linear or non-linear equalization, or a combination of these or other functions. These exemplary conditioning circuits may be implemented using analog and/or digital techniques, and they may either be fixed or adjustable, either manually or by digital control (e.g., using digitally controlled resistance). Exemplary amplifier circuitry 130 are described, for example, with reference to FIG. 4.

The amplified signals from the interposer unit 120 travel to the analyzer 105 via the cable 135. In some implementations, the cable 135 may be optional. For example, the connector assembly 115 can be, in some cases, connected directly to a suitable interface on the analyzer 105. The cable 135 includes one or more transmission lines for individual signals. Each such transmission line may be selected from, for example, a coaxial cable, twinaxial cable (e.g., which may include two wires wrapped inside a shield to carry a differential signal), twisted-pair cable, shielded parallel cable, flex circuit, or other type of shielded or unshielded cable suitable to propagate high speed electrical signals. Any number and/or combination of single-ended and/or differential signals may travel across the cable 135 or interconnects on the connector assembly 115.

In the measurement system 100 depicted in FIG. 1, the analyzer 105 receives signals from the DUT 110 through the interposer unit 120 and the connector assembly 115. For example, the analyzer 105 may include an oscilloscope, a spectrum analyzer, a logic analyzer, a network analyzer, a protocol analyzer, and/or other signal measuring devices. In some examples, the analyzer 105 may perform signal processing operations on the received signals. For example, the analyzer 105 may convert analog signals to digital signals, reduce noise in the received signal, and/or amplify the received signals or decode, count bit-errors, packet-errors, and display the packets and errors communicated between the motherboard 125 and DUT 110. In various examples, the analyzer 105 may display digital signals in a coded format. In some examples, the analyzer 105 may also perform analytical operations on the received signals. In some embodiments, the analyzer 105 may decode the received signals according to a protocol, perform timing analysis (e.g., compute jitter information in the signals), and/or construct histograms using the received signals. For example, the analyzer 105 may analyze (per channel) PCI Express traffic operating at 5 Gbits/second or more.

The analyzer 105 is also connected to communicate with a network 140. The analyzer 105 may transmit, for example, signal processing and/or analysis results to the network 140. In some embodiments, a user device connected to the network 140, such as a computer, may provide a user interface to display measurement results to a user, and may allow the user to control the analyzer 105. Also, a memory device connected to the network 140 may store the received results from the analyzer 105. In some systems, the network 140 may be achieved using a local area network (LAN) and/or a wide area network (WAN), such as the Internet. In other embodiments, a user interface device such as a personal computer may be connected directly to the analyzer 105 without the use of the network 140.

The analyzer 105 may measure signals traveling between the motherboard 125 and the DUT 110. The interposer unit 120 may tap into signals with data rates ranging from near DC to at least 5 Gbits/second (e.g., 5-40 Gbit/second) or from DC to at least 5 Ghz (e.g., 5-40 GHz). In some embodiments, the interposer unit 120 may relay signals having voltage magnitudes ranging from less than about 10 mV to at least about 5 V, such as between about 5 mV and 5 V, 10 mV and 3 V, or about 20 mV and 250 mV, 1 V, 2V, 5V, or 8V. In some embodiments, the interposer unit 120 may also relay single-ended signals or differential signals (e.g., LVDS). The signals may include, but are not limited to, data, control, power, reference voltage or current, power, and/or circuit reference (e.g., ground) signals.

Although only the DUT 110 is shown in FIG. 1, the system 100 may be arranged such that the analyzer 105 receives multiple channels from connector assemblies at each of a number of locations (e.g., multiple PCI Express lanes) on one or more DUTs 110. If multiple probes are used, one or more of the interposer units 120 and/or the connector assemblies 115 may receive and process the high frequency signals.

FIG. 2 shows a view of an exemplary signal tapping structure 200 that includes the interposer unit 120 and the connector assembly 115. The interposer unit 120 connects to a slot 205 on the motherboard 125. In the present embodiment, this connection is shown as a PCI Express slot. The interposer unit 120 is capable of plugging directly into the slot 205 and routing any or all of the signals provided by the slot 205 through the interposer unit 120 where a device such as the DUT 110 can connect to the interposer unit 120 using a device connector 210. This allows the DUT 110 to receive all signals from the slot 205 on the motherboard 125 just as though the DUT 110 were connected directly to the motherboard 125. In some examples, the DUT 110, which can be a graphic or Ethernet card or telecommunication module, for example, may be insertable to mate with the device connector 210, which may be a straddle mount connector, for example. The motherboard may be a PC motherboard, a server motherboard, supercomputer main frame, telecommunication backplane in a chassis, laptop or the like.

The interposer unit 120 also can tap portions of any or all of the signals provided by slot 205 to the connector assembly 115. The connector assembly 115 may be connected to the interposer unit 120 through a flex connector. As shown in this embodiment, the amplifier circuitry 130 interfaces substantially directly to the interposer unit 120 through the tapping connector 215. At the other end of the amplifier circuitry 130, a cable termination 220 connects the amplifier circuitry 130 to the cable 135. An exemplary embodiment of a cable termination method is described in further detail with reference, for example, to FIG. 5. The cable 135 may convey signals between the interposer unit 120 and the analyzer 105 through a cable connector 225.

The device connector 210 on the interposer unit 120 provides an interface suitable for receiving a corresponding connector on the DUT 110, which may be designed to interface in normal operation to the slot 205. In some embodiments, the device connector 210 may be a straddle mount connector. A straddle mount connector can be straddle-mounted to an edge of a PCB with, for example, one or more rows of signal-conducting connectors to connect with corresponding conductive pads provided on one or both sides of the PCB. In other embodiments, the device connector 210 may be a through-hole mounting connector, a surface mounting connector, an edge connector, or any other suitable connection device.

In some embodiments, the device connector 210 may also support the signal and power requirements of the slot 205. In some embodiments, all signals and power supply lines supported by the slot 205 may be connected to the device connector 210. In other embodiments, only the signals and power supply lines required by the specific DUT 110 are introduced to the device connector 210. In some embodiments, if the slot 205 is a PCI Express slot, the device connector 210 may offer any number (e.g., 1, 4, 8 or 16) of high-speed serial PCI Express lanes, each serial lane having differential transmit and receive signal pairs. For example, the device connector 210 and/or the tapping connector 215 may be optimized impedance-controlled straddle mount connectors, such as those commercially available from Techniz of San Jose, Calif. or Samtec of New Albany, Ind., for example.

In the depicted embodiment, the interposer unit 120 taps into the signals which are routed from the slot 205 to the device connector 210, diverting a percentage of the communication to the connector assembly 115. The connector assembly 115 is attached to the interposer unit 120 using the tapping connector 215. In one example, about ten percent of the current may be diverted using tapping resistors within the tapping connector 215. In other embodiments, less than about 1%, 2%, 3%, 5%, 10%, 15%, 20%, or up to at least about 35% of the current passing between the motherboard 125 and the device attached to the device connector 210 may be diverted through the tapping connector 215. In various embodiments, the tapping connector 215 may tap up to about 40%, 50%, 60%, 70%, 80%, or about 90% of the data signal. In some embodiments, the tapping connector 215 may be implemented using a surface mount connector such as those commercially available, for example, from Samtec, Inc. of New Albany, Ind. (e.g., model QSH-DP or QTH-DP) or Techniz of San Jose, Calif. (e.g., model G-FPCN). In other embodiments, a through-hole connector, edge connector, or any other suitable connection device may be used to implement tapping connector 215. Rather than using the tapping connector 215, in some embodiments the interposer unit 120 may be permanently affixed to the connector assembly 115, for example by soldering the amplifier circuitry 130 to the interposer unit 120.

In the depicted embodiment, the amplifier circuitry 130 connects directly to the tapping connector 215. As shown, the amplifier circuitry 130 is implemented using flexible circuitry technology. In some embodiments, the amplifier circuitry 130 may include, but is not limited to, for example a flexible wiring assembly, a PCB, or combination of these or other components or devices. The amplifier circuitry 130 may amplify and/or equalize signals tapped at the interposer unit 120. An exemplary embodiment of the amplifier circuitry 130 is described in further detail with reference, for example, to FIG. 4. In some embodiments, the amplifier circuitry 130 may reside on either or both sides or within multiple layers of a partially rigid or semi-rigid flexible circuit board. In some embodiments, the interface end may be substantially rigid. Additional circuitry may also be implemented within the connector assembly 115, including, but not limited to, noise cancellation, statistics collection, connectivity, functionality screening, monitoring, and/or warning circuitry or the like.

The amplifier circuitry 130 interfaces with the cable 135. In some embodiments, the amplifier circuitry 130 may connect directly to the analyzer 105 via surface straddle mount connectors similar to the tapping connector 215. In the various embodiments, the cable 135 may be implemented using coaxial and/or twinaxial cable. Flex 135 and connector assembly 115 may be provided as a single unit. In some implementations, the cable 135 may be attached to the amplifier circuitry 130 using a direct solder connection. In other embodiments, a flexible circuit-to-cable connector may be provided to interface the amplifier circuitry 130 to the cable 135. The cable 135 may be of any practicable length. In some embodiments, the cable 135 may be implemented 125) and the device connector 210 (e.g., for connection to the DUT 110). The interposer unit 120 can also tap a percentage of these signals to the tapping connector 215.

As illustrated in FIG. 3, the interposer unit 120 can connect to a set of power fingers 310 to supply power to the tapping connector 215 and/or the device connector 210. For example, each power finger 310 may be a 6-pin power socket coupled to wide traces that pass through the interposer unit 120. In some embodiments, the power signal supplied to the tapping connector 215 may be used, for example, to power the amplifier circuitry 130. In various examples, any number of power signals may be accessed and routed through the interposer unit 120. In some embodiments, an external power source (e.g., on-board battery supply, wired AC power source, USB (universal serial bus) power, or the like) may be connected to the interposer unit 120 and/or the device connected to the tapping connector 215, for example, to power any signal conditioning circuitry which may exist within either the interposer unit 120 or a device connected to the tapping connector 215.

Signals received at the slot connector 305 can also be directed to both the device connector 210 and the tapping connector 215 through the interposer unit 120. As illustrated in FIG. 3, signals communicated through the slot connector 305 may be configured as a set of differential pairs 315 as are, for example, the signals propagated by a PCI Express connection. Any or all of the differential pairs 315 accessed at the slot connector 305 can be routed through the interposer unit 120 to the device connector 210 and/or the tapping connector 215. A set of ground pads 320 is provided between each of the differential pairs 315. The ground pads 320 may advantageously improve, for example, signal integrity at the connection between the slot connector 305 and the interposer unit 120, the connection between the interposer unit 120 and the tapping connector 215, and/or the connection between the interposer unit 120 and the device connector 210.

The signals from differential pairs 315 are tapped at the tapping connector 215 through the tapping resistors 325. A percentage of the signals carried by the differential pairs 315 may be diverted to a device attached to the tapping connector 215. In some embodiments, tap resistors 325 can be used to divert a percentage of these signals from the interposer unit 120 to a device attached to tapping connector 215. In some embodiments, the main traces of differential pairs 315 may be substantially insulated from signal disruption due to, for example, device insertion at the tapping connector 215 through the use of solder masks between the main traces of differential pairs 315 and the tapping connector 215.

FIG. 4 shows an exemplary electrical circuit representation of a signal path for high speed signal amplification through the amplification circuitry 130. An exemplary embodiment of the amplifier circuitry is described in U.S. patent application Ser. No. 11/508,583 entitled “Probing High-Frequency Signals” by Sutono et al., filed on Aug. 22, 2006. The disclosure of the detailed description portions and corresponding figures from U.S. patent application Ser. No. 11/508,583 is incorporated herein by reference. In the depicted example, the amplifier circuitry 130 includes an input stage 405, a termination stage 415, an output equalizer 420, and an output stage 425. The received signals may propagate from the input stage 405 to the output stage 425 through the connector assembly 115 between the interposer unit 120 and the analyzer 105. In some embodiments, the input stage 405 may reside within the interposer unit 120 and/or the tapping connector 215 rather than the amplifier circuitry 130.

In some embodiments, the input stage 405 may include the differential pairs 315 and the tap resistors 325 of the interposer unit 120. The tap resistors 325 may reduce loading of the received signals. Additionally, parasitic capacitance and/or inductance at the contact between the interposer unit 120 and the connector assembly 115 may be substantially mitigated, for example, by directly contacting the tap resistors 325 with the interposer unit 120.

In some embodiments, an example of which may relate to the tapping connector 215 described with reference to FIG. 2, the tap resistors 325 may include a resistive material that may be applied (e.g., coated) on one or more tips of the connection pins on the connector assembly 115. The resistance of coatings applied to a pin may be controlled, for example, using processes that may include, but are not limited to, chemical vapor deposition or electron beam evaporation. In some embodiments, the tap resistors 325 may be integrated entirely within the interposer unit 120, the tapping connector 215, or the pins of the connector assembly 115. In other embodiments, the tap resistors 325 may be integrated partially on the tips of the connection pins and partially in the amplification circuitry 130 (e.g., as a printed resistor, surface mounted resistor, etc.). For example, one of the tap resistors 325 may be implemented in part by resistive material coated on the tip of the corresponding connection pin and in part with one or more circuit elements in the amplifier circuitry 130. In one example, the input stage 405 may include resistors of high precision implemented in the amplifier circuitry 130 and a layer of coated resistive material with lower precision on the tips of the connection pins. Such embodiments may advantageously reduce high frequency (e.g., capacitive) loading effects.

Leading into the termination stage 415 are a set of transmission lines 430. The incoming transmission lines 430, in some embodiments, may come from the cable 135, the interposer unit 120, and/or the tapping connector 215, or they may be included as part of the amplifier circuitry 130. The transmission lines 430 carry a portion of the signals from the differential pairs 315.

In the depicted example, the termination stage 415 may include dual high-speed op-amps 460 and feedback resistors 465. A reference voltage (e.g., a ground potential) is established at positive inputs of the op-amps 460 so that negative inputs of the op-amps 460 may be established as a virtual ground. For example, termination resistors 470 connected to the negative inputs of the op-amps 460 may provide termination for an input transmission line, including the tapping connector 215, the cable 135, and the amplifier circuitry 130.

A gain in the termination stage 415 may be related to a ratio between the resistance of the feedback resistors 465, the resistance of the tap resistor 320, and the resistance of the termination resistors 470. Here, the termination stage 415 may amplify the received signals using the feedback resistors 465, the tap resistors 325, and the termination resistors 470. In various examples, the termination stage 415 may amplify the received signals when the feedback resistors 465 have resistance greater than the sum of the resistance of the tap resistors 325 and the termination resistors 470. In some examples, a manufacturer may set the resistance of the feedback resistor 470 to be substantially equal to the sum of the resistance of the termination resistor 470 and the tap resistor 430 to give a unity gain in the termination stage 415.

In some embodiments, the non-inverting terminal may receive a voltage other than ground, such as a voltage from a voltage reference source or a sinusoidal signal containing phase information. In various embodiments, an operational amplifier circuit in the termination stage 415 may be implemented on flexible circuitry.

The output equalizer 420 includes capacitors 445, series resistors 450, and parallel resistors 455. The parallel resistors 455 may match the input and output impedance of the output stage 425 to reduce signal reflections. In this example, the output equalizer 420 is a differential pi equalizer that compensates high-frequency losses (e.g., due to the connection with the cable 135) in the output stage 425. In some embodiments, the output equalizer 420 may be adjustable. For example, the parallel resistors 455 may be variable resistors that are adjustable to adjust the bandwidth of the output equalizer 420. In some embodiments, the output equalizer 420 may be etched upon flexible circuitry, for example within the amplifier circuitry 130.

The output stage 425 includes a transmission line 475 and termination resistors 480. In some embodiments, the output stage 425 may be incorporated into the cable connector 225 and/or the analyzer 105. In various embodiments, the output equalizer 420 may be incorporated into the analyzer 105. In the example in which the output equalizer 420 is incorporated into the analyzer 105, a set of transmission lines out 435 may lead from the termination stage 415 to the output equalizer 420. The transmission lines out 435 may be part of the amplifier circuitry 130, the cable 135, or the cable connector 225. In some examples, the transmission lines 435 and/or 475 may include a cable or other flexible wiring assembly, flexible circuitry, or PCB traces. The analyzer 105 or the cable 135 may receive signals from the output stage 425.

Some or all of the electrical components in the amplifier circuitry 130 may be constructed on a flexible wiring assembly, for example within flexible circuitry. Stages of the amplifier circuitry 130 may be added, removed, or arranged in a different sequence. For example, rather than or in addition to the output equalizer 420, an input equalizer may be placed between the input stage 405 and the termination stage 415. In some embodiments, an input equalizer may form a high pass filter (HPF) that may at least partially compensate for high-frequency signal losses associated with PCB traces within the interposer unit 120. For example, there may be some signal attenuation in the PCB traces. In some embodiments, an equalizer may substantially flatten the frequency response by introducing high-pass filter like response to compensate the low-pass filter-like response of the channel caused by losses, such as the interconnect losses. By reducing the signal losses, the input equalizer may reduce intersymbol interference (ISI) and improve bit error rate (BER).

In some examples, the ground traces at some interfaces (e.g., the tapping connector 215 and/or the cable connector 225) may include vias spaced such that the first resonant frequency is substantially greater than the frequency band of interest. In some embodiments, due to the construction of the vias, special treatment of the resonance frequency may be required. Methods of dampening the via resonances are described in greater detail with reference to FIGS. 6, 7, and 8. In some examples, ground planes at interfaces (e.g., the tapping connector 215, the cable transition 220, and/or the cable connector 225) may be etched to reduce capacitance at the interfaces.

FIG. 5 shows an exemplary cable transition 220 constructed by soldering or otherwise coupling the amplifier circuitry 130 to the cable 135 within the connector assembly 115. As illustrated in FIG. 5, the amplifier circuitry 130 may be constructed of flex-to-install. In various implementations, the interconnects may be substantially flexible from the connector 215 to the cable transition 220. At the cable transition 220, the flex may be substantially made of rigid flex circuitry (e.g., layered with rigid materials to create a less flexible material similar to traditional PCB). In other embodiments, fully flexible circuitry may be used. The cable 135, in some implementations, may be constructed of differential pairs 315. The differential pairs 315 may be embodied, for example, in coaxial or twinaxial cable. In some embodiments, the cable 135 may include an assembly jacket 505 to protect and contain the individual transmission lines. Cable transition 220 and cable 135 may or may not be necessary as connector assembly 115 may comprise all flexible material.

In some embodiments, if the amplifier circuitry 130 is constructed of a multi-sided flex circuitry, individual transmission wires can be separated into two rows (e.g., every other wire), and soldered to both the top and bottom of the amplifier circuitry 130. In various examples, all wires may be soldered to a single side of the amplifier circuitry 130. In other embodiments, the cable 135 may be terminated by a connector, such that the connector plugs into a connector on the amplifier circuitry 130. In one example, a straddle mount connector may be attached to the edge of multi-layer rigid-flex circuitry to enable the connection between the amplifier circuitry 130 and the cable 135.

FIG. 6 shows an exemplary cross-section view of a multilayer circuit board layout 600 that includes features for dampening resonant high frequency energy at with shielded or unshielded ribbon cable, tri-axial cable, or other non-flexible-circuitry wiring methods.

A cable connector 225 may be used to interface the cable 135 to a test device, such as the analyzer 105. In some embodiments, the cable connector 225 may be implemented using a commercially available PCI Express cable connector technology such as, for example, InfiniBand, iPass Interconnect by Molex Inc. of Lisle, Ill., or HDRFI (High Frequency RF Interconnect) by Tensolite Co. of St. Augustine, Fla., Samtec of New Albany, Ind., for example. In some implementations, the cable 135 may connect to the analyzer 105 via a vertical, straddle mount, or edge type connector.

In some embodiments, the amplifier circuitry 130 may be connected between the cable 135 and the test device (e.g., analyzer 105) or at an intermediate position along the cable 135. In various embodiments, the entire connector assembly 115 may be implemented in a single technology, such as flexible circuitry. In an illustrative example, the connector assembly 115 may connect directly to a connector on the interposer unit 120 and to the analyzer 105 through an appropriate number of coaxial or triaxial wires.

FIG. 3 shows an exemplary electrical circuit layout 300 on the interposer unit 120. In the depicted example, provision is made for tapping and routing high frequency content signals being conveyed along transmission lines through the interposer unit 120. The signals may include analog and/or digital data signals and/or power signals. The signals are routed on traces on the interposer unit 120. The traces run between a slot connector 305 (e.g., for connection to the slot 205 on the motherboard a via on the interposer unit 120, for example. In some embodiments, when a multilayer unit (e.g., interposer unit 120) is connected to a slot (e.g., slot 205), a via may be required to connect to a different layer of the unit.

Resonances associated with vias may degrade signal integrity. Via resonances may be controlled by appropriate implementation of a damping resistance. For example, a damping resistor may be placed in series with a stub which accesses the via. In some examples, a stub may be formed from a section of transmission line. A connection pin or via signal path, for example, may behave as a stub with a resonant frequency.

As shown in FIG. 6, a transmission line 605 connects with a stub 610. For example, the transmission line 605 may be introduced into the interposer unit 120 by a signal pin illustrated as the stub 610. The transmission line 605 may be, for example, a stripline trace through the interposer unit 120 to the slot 205 on the motherboard 125. The stub 610 interfaces with a damping resistor 615. The damping resistor 615 is routed to a ground pin 620. The ground pin 620 connects to a ground trace 625. In one example, the ground pin 620 may be found within the slot 205. In other embodiments, the stub 610 may be routed outside of the area of slot 205 where the damping resistor 615 may be added and grounded. The damping resistor 615 may be sized such that it does not load the main interconnects. In some implementations, a known impedance may be introduced to the transmission line 605, for example using a resistor in series with the via. The damping resistor 615 may then be sized in relation to the series impedance to generate a known damping effect.

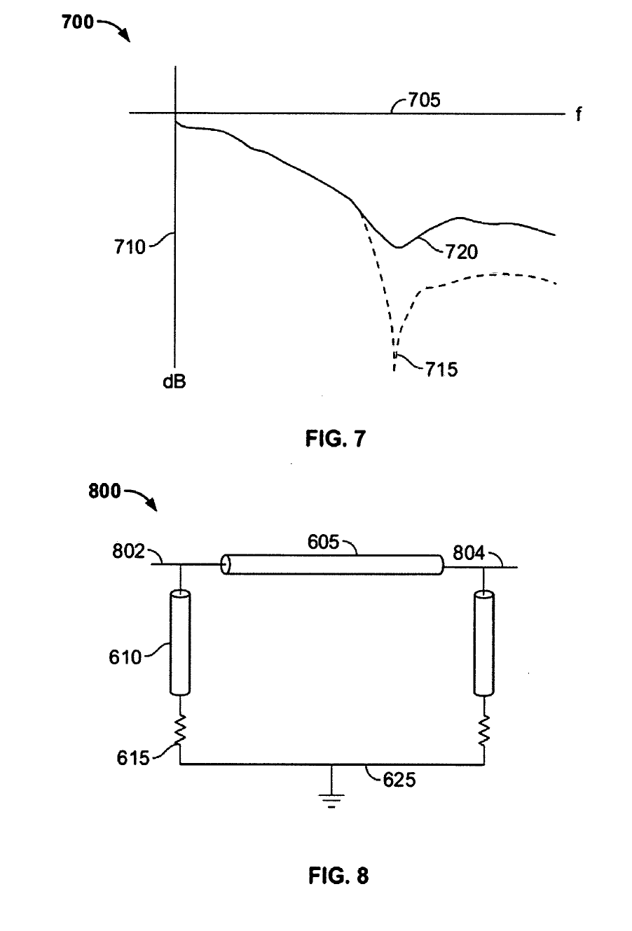

FIG. 7 shows an exemplary graph 700 of the effect the dampening resistor 615 may have on frequency response at a via using the circuit layout 600 in FIG. 6. The x-axis 705 plots frequency, while the y-axis 710 plots signal transmission in decibels. A first plot 715 demonstrates the sharp effect on frequency response at a via when no damping resistor is in use. In the case of plot 715, the stub 610 connected to the transmission line 605 may act like a quarter wave resonator. A second trace 720 provides a muted comparison effect on frequency response, this time with the damping resistor 615 in series with the stub 610 to the ground pin 620. The trace 720 indicates a substantial reduction in the resonance Q-factor. The damping resistor 615 dampens the resonance at the stub connection.

FIG. 8 shows an exemplary circuit schematic 800 for dampening resonance at a via associated with the transmission line 605. The schematic 800 includes may represent, for example, a model of a circuit (e.g., at a via associated with the resistor 615), which may include a model of the via 610 (FIG. 6) and associated traces routed through the inner layer(s) of a PCB.

In the depicted example, the transmission line 605 is on a multilayer circuit board and connects between two nodes 802, 804. The nodes 802, 804 each connect through a corresponding stub 610 in series with a damping resistor 615 to a reference node 625, which is a circuit ground reference in the depicted example. In an illustrative embodiment, the node 802 may represent a node connected to the connector pin at the slot 205. The combination of the stub 610 and the damping resistor 625 may decrease resonant effects associated with either of the stubs 610.

The transmission line 605 then runs along a trace within the multilayer circuit board. A second node 804 marks the re-emergence of the transmission line 605 from the multilayer circuit board. For example, if the transmission line 605 is propagated through a middle layer of a multi-layer circuit board, it may have to be routed back to an outer layer using a via to continue into a connecting device. In some embodiments, the node 804 may represent the connection of the interposer unit 120 to the connector assembly 115 as it pertains to the individual transmission line 605. As with the node 802, the node 804 connects to a stub. The stub connected to node 804 is in series with a resistor to ground. This connection may act to dampen resonance at the point of transition where the transmission line changes layers at the node 804 in the multilayer circuit board.

In other embodiments, the via marked by the node 802 may transfer the transmission line 605 from one side of a double-sided or multilayer circuit board to the other. At the next point of connection, in this example, the signal may be accessible to a connecting device from that side of the board without requiring a second via and/or a second stub and dampening resistor.

Although various embodiments that may be implemented in the system 100 of FIG. 1 have been described, other embodiments and features may be implemented in various systems and apparatus, or using other methods either alone or in combination. In various examples, the connector assembly 115 may be coupled to the interposer unit 120 and/or to the analyzer 105 through a second wiring assembly, which may be, for example, a shielded or unshielded ribbon cable, coaxial cable, twinaxial cable, or other flexible wiring media. In an illustrative example, the amplifier circuitry 130 may connect directly to the tapping connector 215 on the interposer unit 120 and to the analyzer 105 through an appropriate number of coaxial or triaxial wires. In various embodiments, each of the tapping circuits included on the interposer unit 120 and/or the tapping connector 215 may tap a portion of the data signal, where the tapped portion may represent less than about 20% of the data signal, for example. In some other examples, the tapped portion may represent about 1%, or up to about 5%, 10%, 20%, 30%, 40%, 50%, 60%, 70%, 80%, or about at least 90% of the data signal.

In some implementations, active signal processing within the amplifier circuitry 130 may include active amplification using, for example, transistor amplification. In some embodiments, signal amplification may involve substantially unity gain or more than unity gain over a frequency range. In some other embodiments, signal amplification may involve substantially more or less than unity gain over a frequency range. In some embodiments, signal amplification may involve signal inversion (e.g., multiply by negative one).

In an illustrative example, an apparatus for use with a waveform processing system may include an interposer unit to substantially convey one or more data signals between a first circuit assembly on a first printed circuit board and a second circuit assembly on a second printed circuit board. The system further includes a flexible wiring assembly to receive a portion of each of the data signals when the flexible wiring assembly is coupled to the interposer unit. In addition, the system may include a signal conditioning module that actively conditions the received portions of each of the data signals. The conditioned signals are suitable for transmission through the flexible wiring assembly to a waveform processing device. The signal conditioning module may be integrated on the flexible wiring assembly. In some exemplary systems, the flexible wiring assembly may include a flexible circuit.

Some systems may include at least one tapping circuit associated with each of the data signals, and each tapping circuit may be arranged on the interposer unit to tap a corresponding one of the portions to be received by the flexible wiring assembly. Some tapping circuits may tap less than about 10%, or about 20%, 30%, or up to 95% of any of the data signals.

The signal conditioning assembly may include an amplifier circuit to amplify at least one of the received signals. The signal conditioning module may include a control input, and, for example, the control input may be configured to receive a control signal from the waveform processing device. A gain applied to at least one of the received data signals may be responsive to a control signal received at the control input.

The signal conditioning module may operate in response to a digital signal received at the control input. In some examples, the interposer unit may substantially pass through a power signal between the first circuit assembly and the second circuit assembly, and the flexible wiring assembly may receive a portion of the power signal. In various embodiments, the signal conditioning module may receive operating power and/or reference signals (e.g., current and/or voltage reference) from the power signal received from the interposer unit and/or from signals received from a waveform processing device. Some systems may further include a second wiring assembly to couple the data signals from the interposer unit to the flexible wiring assembly.

The waveform processing device may include, but is not limited to, a protocol analyzer, spectrum analyzer, network analyzer, digital oscilloscope, digital storage oscilloscope, logic analyzer, data logger, or a combination of these and/or other systems that may acquire and/or process samples of at least one data signal.

The interposer unit may convey one or more of the data signals between the first circuit assembly and the second circuit assembly. In another illustrative example, a method to process waveforms may include conveying a plurality of data signals between a first circuit assembly on a first printed circuit board and a second circuit assembly on a second printed circuit board. The method may further include receiving a portion of each of the data signals on a flexible wiring assembly when the flexible wiring assembly is coupled to the interposer unit. The method may also include conditioning the received portions of each of the data signals with an active signal conditioning module that is integrated on the flexible wiring assembly. Finally, the method may include conveying the conditioned signals through the flexible wiring assembly to a waveform processing device.

In various embodiments, the size of the interposer unit may advantageously be reduced, thereby yielding potentially improved signal integrity, performance, and reduced cost. For example, the only components mounted on the substrate of the interposer module may be only tapping resistors, or tapping resistors and any required connectors needed to mate the interposer unit to the host processing system (e.g., motherboard of a computer system), device under test, and/or the flexible wiring assembly. In various examples, the substrate may be sized to have a maximum dimension less than about 160%, 140%, 120%, 110%, 105% or substantially about 100% of a width of the widest of the host and DUT electrical interfaces. In an orthogonal dimension, the substrate may advantageously be made as short as practicable given the dimensions and placement requirements of traces (or other electrically conductive pathways in the interposer module), and any necessary clearances between the (optional) connectors. Various connector styles (edge, right angle, fingers, and the like) may be selected to substantially minimize the dimensions, in particular the path length of electrical signals being conveyed between the host system and the DUT, for example.

Various embodiments may include other hardware and/or software. For example, a waveform processing device, such as a protocol analyzer, may supply a wired or wireless (e.g., infrared, radio frequency (RF), optical) control signal to adjust the operation (e.g., gain, filter settings) of one or more digital and/or analog circuits in the amplifier circuitry 130 and/or the interposer unit 120. The signal conditioning (e.g., filtering, attenuation, and/or amplification) applied to each signal may be independently controlled, for example, by individually addressing or sequentially encoding information in the control signal. In some embodiments, the waveform processing device may be included within the analyzer 105.

A number of embodiments have been described. Nevertheless, it will be understood that various modifications may be made. For example, advantageous results may be achieved if the steps of the disclosed techniques were performed in a different sequence, if components in the disclosed systems were combined in a different manner, or if the components were replaced or supplemented by other components. Accordingly, other embodiments are within the scope of the following claims.

1. An apparatus for monitoring signals between a motherboard and a system being tested, the apparatus comprising:
a first printed circuit board comprising a device under test (DUT) and comprising one or more standard computer peripheral connector;
a second printed circuit board comprising a host processing system to communicate with the device under test (DUT) when the DUT is coupled to a corresponding one or more standard computer peripheral connector of the host processing system;
an interposer unit to substantially convey a plurality of data signals between the host processing system and the DUT, the interposer unit adapted to receive the one or more standard computer peripheral connector of the DUT and adapted to be coupled to the corresponding one or more standard computer peripheral connector of the host processing system;
a flexible wiring assembly to couple one or more of the plurality of data signals from the interposer unit to a waveform processing device; and
a signal conditioning module to condition the one or more of the plurality of data signals for transmission though said flexible wiring assembly to the waveform processing device, the signal conditioning module being integrated on said flexible wiring assembly.

2. The apparatus of claim 1, wherein the second printed circuit board comprises a motherboard for use in a computer system.

3. The apparatus of claim 1, wherein the interposer unit further comprises a tapping circuit to couple the plurality of data signals to the flexible wiring assembly.

4. The apparatus of claim 1, wherein the flexible wiring assembly comprises a semi-rigid portion, and at least a portion of the signal conditioning module is integrated on the semi-rigid portion.

5. An apparatus for use with a waveform processing system, the apparatus comprising:
an interposer unit to substantially convey a plurality of data signals between a standard computer peripheral conductor of a first circuit assembly on a first printed circuit module and a standard computer peripheral conductor of a second circuit assembly on a second printed circuit module;
a flexible wiring assembly to receive a portion of each of the plurality of data signals when the flexible wiring assembly is coupled to the interposer unit; and
a signal conditioning module to actively condition said received portions of each of the plurality of data signals for transmission through said flexible wiring assembly to a waveform processing device, the signal conditioning module being integrated on said flexible wiring assembly.

6. The apparatus of claim 5, wherein the interposer unit further comprises a tapping circuit to couple the plurality of data signals to the flexible wiring assembly.

7. The apparatus of claim 5, wherein the flexible wiring assembly comprises a flexible circuit.

8. The apparatus of claim 5, further comprising at least one tapping circuit associated with each of the plurality of data signals, each tapping circuit being arranged on the interposer unit to tap a corresponding one of said portions to be received by the flexible wiring assembly

9. The apparatus of claim 8, wherein each tapping circuit taps less than about 20% of each of the data signals.

10. The apparatus of claim 8, wherein each tapping circuit taps less tan about 10% of each of the data signals.

11. The apparatus of claim 5, wherein the signal conditioning module comprises an amplifier circuit to amplify at least one of the received signals.

12. The apparatus of claim 11, wherein the amplifier circuits produces an output signal with a waveform that substantially corresponds within a frequency band of interest to a waveform of at least one of the received signals.

13. The apparatus of claim 12, wherein the output signal produced by the amplifier circuit has an amplitude within the frequency band of interest that is greater than an amplitude of the corresponding received signal.

14. The apparatus of claim 12, wherein the output signal produced by the amplifier circuit has an amplitude within the frequency band of interest that is substantially the same as an amplitude of the corresponding received signal.

15. The apparatus of claim 12, wherein the output signal produced by the amplifier circuit has substantially reduced gain for portions of the received signal that substantially exceed a threshold amplitude.

16. The apparatus of claim 5, wherein the signal conditioning module comprises a variable control input to controllably adjust operation of the signal conditioning module.

17. The apparatus of claim 16, wherein the variable control input is to receive a control signal from the waveform processing device.

18. The apparatus of claim 17, wherein the control signal comprises a gain control signal.

19. The apparatus of claim 17, wherein the control signal comprises a digital signal.

20. The apparatus of claim 5, wherein the interposer unit is further to substantially convey a power signal between the first circuit assembly and the second circuit assembly, and the flexible wiring assembly is further to receive a portion of the power signal.

21. The apparatus of claim 20, wherein the signal conditioning module receives operating power from the received power signal.

22. The apparatus of claim 5, wherein the signal conditioning module receives operating power from the waveform processing device.

23. The apparatus of claim 5, wherein the flexible wiring assembly is coupled to the interposer unit though a second wiring assembly.

24. The apparatus of claim 5, the waveform processing device comprises a protocol analyzer.

25. The apparatus of claim 5, the waveform processing device comprises an oscilloscope.

26. The apparatus of claim 5, the waveform processing device comprises a logic analyzer.

27. The apparatus of claim 5, the waveform processing device comprises an acquisition system to acquire samples of at least one of the data signals.

28. The apparatus of claim 5, wherein the interposer unit comprises a printed circuit board.

29. A method to process waveforms, the method comprising:
conveying a plurality of data signals via an interposer unit between a standard computer peripheral conductor of a first circuit assembly on a first printed circuit module and a standard computer peripheral conductor of a second circuit assembly on a second printed circuit module;
receiving a portion of each of the plurality of data signals on a flexible wiring assembly when the flexible wiring assembly is coupled to the interposer unit;
conditioning said received portions of each of the plurality of data signals with an active signal conditioning module integrated on said flexible wiring assembly; and
conveying said conditioned signals through said flexible wiring assembly to a waveform processing device.

30. The method of claim 29, wherein receiving the portion of each of the plurality of data signals further comprises tapping each of the plurality of data signals with a tapping circuit arranged on the interposer unit.

31. The method of claim 29, wherein conditioning said received portions of each of the plurality of data signals comprises amplifying at least one of the received signals.

32. The method of claim 29, further comprising adjusting operation of the signal conditioning module in response to a control signal.

33. The method of claim 32, further comprising receiving the control signal from the waveform processing device.

34. The method of claim 29, further comprising drawing power to operate the signal conditioning module from a signal on the interposer unit.

35. The method of claim 29, further comprising drawing power to operate the signal conditioning module from the waveform processing device.

36. An apparatus for use with a waveform processing system, the apparatus comprising:
an interposer unit to substantially convey at least one data signal between a standard computer peripheral conductor of a first circuit assembly on a first printed circuit module and a standard computer peripheral conductor of a second circuit assembly on a second printed circuit module; and
means for actively conditioning a portion of each of the at least one data signals and for conveying said conditioned signals to a waveform processing device.

37. The apparatus of claim 36, wherein said conditioning means comprises a means for receiving a portion of each of the at least one data signals when said conditioning means is coupled to the interposer unit.

38. The apparatus of claim 36, wherein the interposer unit further comprises means for dampening resonant high frequency energy at a via on the interposer unit.

39. An apparatus for use with a waveform processing system, the apparatus comprising:
an interposer unit comprising a printed circuit substrate with conductive pathways to substantially convey at least one data signal between a first electrical interface comprising a standard computer peripheral conductor of a first circuit assembly on a first printed circuit module and a second electrical interface comprising a standard computer peripheral conductor of a second circuit assembly on a second printed circuit module, and further comprising a tapping resistor associated with each of the data signals to be coupled to a third electrical interface to a flexible wiring assembly that, when coupled to the third electrical interface, conveys the coupled signals from the interposer unit to a waveform processing system; and
a signal conditioning module integrated on said flexible wiring assembly to condition the one or more data signals for transmission through said flexible wiring assembly to the waveform processing system.

40. The apparatus of claim 39, wherein the only components mounted on the substrate include any tapping resistors associated with the third electrical interface.

41. The apparatus of claim 39, wherein the only components mounted on the substrate include the tapping resistors associated with the third electrical interface.

42. The apparatus of claim 39, wherein the substrate is sized to have a maximum dimension of less than about 110% of a width of the widest of the first and second electrical interfaces.
